(19) United States
(12) Patent Application Publication
(10) Pub. No.: US 2011/0013789 A1
(43) Pub. Date: Jan. 20, 2011

(54) ELECTROMAGNETIC INTERFERENCE SHIELDING STRUCTURE AND VOICE COIL MOTOR HAVING SAME

(75) Inventor: GA-LANE CHEN, Santa Clara, CA (US)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/629,131

(22) Filed: Dec. 2, 2009

(30) Foreign Application Priority Data
Jul. 15, 2009 (CN) 200910304386.4

(51) Int. Cl. H04R 25/00; H05K 9/00

(52) U.S. Cl. 381/189; 174/394; 361/818

(57) ABSTRACT

An exemplary electromagnetic interference shielding structure, includes a substrate and a metallic film formed on at least one surface of the substrate. The substrate is made of an alloy of Ni and Fe, and the metallic film is made of an alloy of Ni, Fe, Cu and Mo.

### BACKGROUND

1. Technical Field

The present disclosure relates to electromagnetic interference (EMI) shields, and particularly, to an EMI shielding structure and a voice coil motor having the EMI shielding structure.

2. Description of Related Art

EMI shielding structures have been widely used for preventing electrical interference or magnetic interference between two areas.

Voice coil motors are usually used as actuators in camera modules. Magnets and electrical wires are used in the voice coil motors, such that EMI prevention is important for other electronic devices in the camera modules.

Currently, a single metal sheet or panel is usually used as an EMI shielding structure. However, usually, a single metal piece is not satisfactory for many applications.

What is needed, therefore, is an EMI shielding structure which can overcome the above shortcomings, and a voice coil motor having the EMI shielding structure.

### BRIEF DESCRIPTION OF THE DRAWINGS

Many aspects of the present EMI shielding structure and voice coil motor can be better understood with reference to the following drawings. The components in the drawings are not necessarily drawn to scale, the emphasis instead being placed upon clearly illustrating the principles of the present EMI shielding structure and voice coil motor. Moreover, in the drawings, like reference numerals designate corresponding parts throughout the several views.

FIG. 1 is a cross-sectional view of an EMI shielding structure in accordance with a first embodiment.

FIG. 2 is a cross-sectional view of an EMI shielding structure in accordance with a second embodiment.

FIG. 3 is a schematic view showing a voice coil motor in accordance with a third embodiment, the voice coil motor having an EMI shielding shell made of the EMI shielding structure shown in either FIG. 1 or FIG. 2.

### DETAILED DESCRIPTION OF THE EMBODIMENTS

Embodiments of the present electromagnetic interference (EMI) shielding structure and voice coil motor will now be described in detail below and with reference to the drawings.

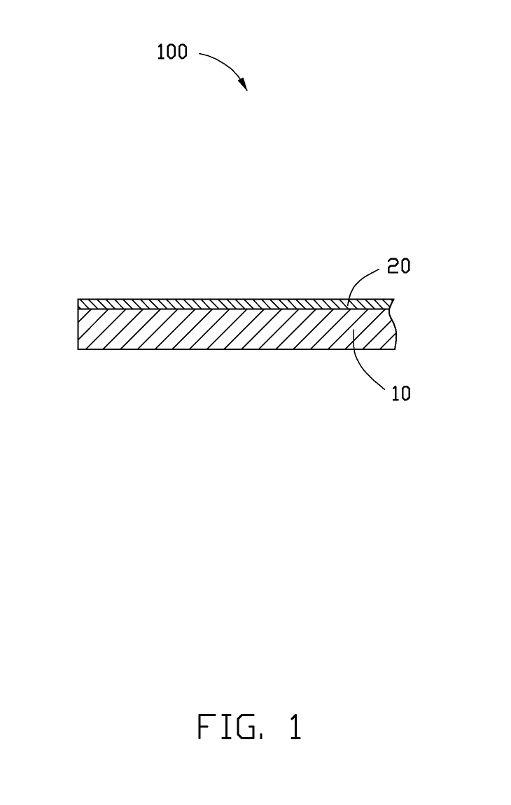

Referring to FIG. 1, an EMI shielding structure 100 in accordance with a first embodiment, is provided. The EMI shielding structure 100 includes a substrate 10, and a metallic film 20 formed onto a surface of the substrate 10.

The substrate 10 is made of an alloy of nickel (Ni) and ferrum (Fe). Wherein, Ni has a weight percentage (wt %) in a range from 78 to 82 (78%≦wt %≦82%); and Fe has a weight percentage in a range from 18 to 22 (18%≦wt %≦22%).

The metallic film 20 is made of an alloy of Ni, Fe, copper(Cu) and molybdenum (Mo). Wherein, Ni has a weight percentage (wt %) in a range from 73 to 79 (76%≦wt %≦78%); Fe has a weight percentage in a range from 17 to 23 (17%≦wt %≦23%); Cu has a weight percentage in a range from 2 to 5 (2%≦wt %≦5%); and Mo has a weight percentage in a range from 2 to 5 (2%≦wt %≦5%). Preferably, Ni has a weight percentage in a range from 76 to 78 (76%≦wt %≦78%); Fe has a weight percentage in a range from 17 to 19 (17%≦wt %≦19%); Cu has a weight percentage in a range from 3 to 4 (3%≦wt %≦4%); and Mo has a weight percentage in a range from 2 to 4 (2%≦wt %≦4%).

The metallic film 20 can be formed on the substrate 10 by sputtering deposition. The metallic film 20 and the substrate 10 both includes Ni and Fe, such that the metallic film 20 has wettability to the substrate 10, and thus the metallic film 20 can be fixedly adhered to the substrate 10. Cu improves electrical conductivity of the metallic film 20, such that the metallic film 20 has a higher EMI shielding capability. The weight percentage of Mo used in the metallic film 20 strengthens the metallographic structure of the metallic film 20, thus the metallic film 20 can have a higher mechanical strength. In contrast, excessive Mo would lead to breakdown of the metallographic structure of the metallic film 20.

In operation, the EMI shielding structure 100 can be formed as a panel or a shell, and the metallic film 20 directly faces an electrical field or magnetic field to be shielded. The metallic film 20 can absorb electromagnetic waves from the electrical field or the magnetic field. The metallic film 20 has the greater EMI shielding capability and the greater mechanical strength, such that the thickness of the metallic film 20 can be thinned down. In particular, when a thickness of the substrate is in a range from 50 μm to 1000 μm, the thickness of the metallic film can be in a range from 100 nm to 1000 nm.

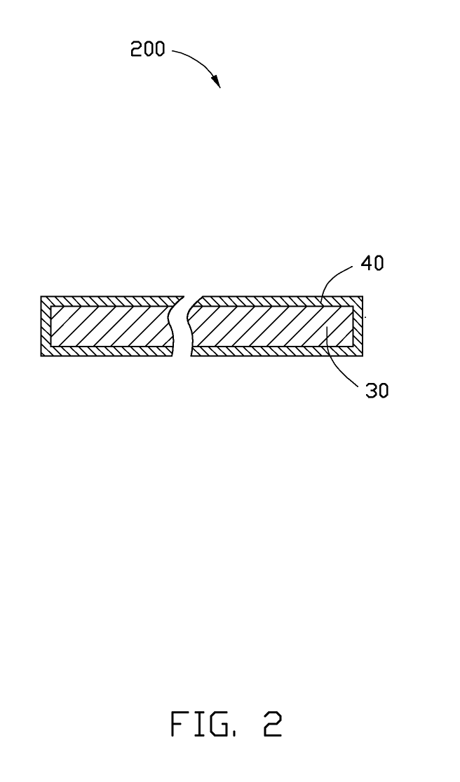

Referring to FIG. 2, an EMI shielding structure 200 in accordance with a second embodiment, is provided. The EMI shielding structure 200 includes a substrate 30 and a metallic film 40, but in this embodiment the metallic film 40 is formed on the entire surface of the substrate 30. The substrate 30 and the metallic film 40 are otherwise the same as the substrate 10 and the metallic film 20 described above.

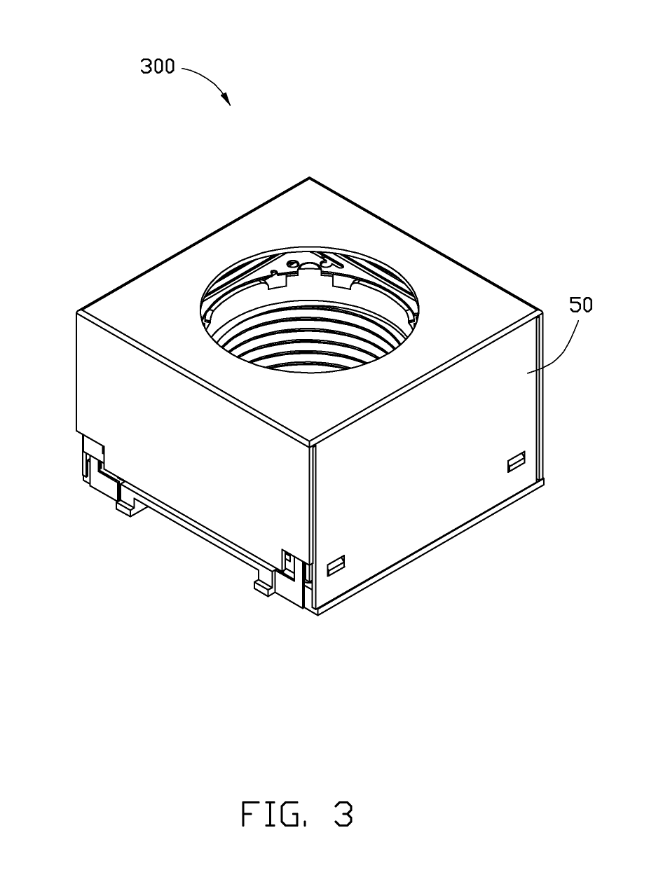

Referring to FIG. 3, a voice coil motor 300 in accordance with a third embodiment, is provided. The voice coil motor 300 has an EMI shielding shell 50 for enclosing a voice coil module (not labeled) therein. The shell 50 includes a plurality of panels of the EMI shielding structure 100 (or 200) described above. The metallic film 20 (or 40) described above is the inmost surface of the entire shell 50, and the metallic film 20 (or 40) directly faces the voice coil module.

It is understood that the above-described embodiments are intended to illustrate rather than limit the embodiment. Variations may be made to the embodiments and methods without departing from the spirit of the invention. Accordingly, it is appropriate that the appended claims be construed broadly and in a manner consistent with the scope of the embodiment.

What is claimed is:

1. An electromagnetic interference shielding structure, comprising:
a substrate made of an alloy of Ni and Fe; and
a metallic film formed onto at least one surface of the substrate, the metallic film being made of an alloy of Ni, Fe, Cu and Mo.

2. The structure as described in claim 1, wherein the metallic film contains Ni in a weight percentage in a range from 73 to 79, Fe in a weight percentage in a range from 17 to 23, Cu in a weight percentage in a range from 2 to 5, and Mo in a weight percentage in a range from 2 to 5.

3. The structure as described in claim 2, wherein the metallic film contains Ni in a weight percentage in a range from 76 to 78, Fe in a weight percentage in a range from 17 to 19, Cu in a weight percentage in a range from 3 to 4, and Mo in a weight percentage in a range from 2 to 4.

4. The structure as described in claim 1, wherein the substrate contains Ni in a weight percentage in a range from 78 to 82, and Fe in a weight percentage in a range from 18 to 22.

5. The structure as described in claim 1, wherein a thickness of the substrate is in a range from 50 μm to 1000 μm.

6. The structure as described in claim 5, wherein a thickness of the metallic film is in a range from 100 nm to 1000 nm.

7. The structure as described in claim 1, wherein the metallic film is formed onto the entire outer surface of the substrate.

8. A voice coil motor, comprising an electromagnetic interference shielding shell, and a voice coil module received in the shell, the shell comprising a substrate made of an alloy of Ni and Fe; and a metallic film formed on at least one surface of the substrate, the metallic film being made of an alloy of Ni, Fe, Cu and Mo.

9. The voice coil motor as described in claim 8, wherein the metallic film contains Ni in a weight percentage in a range from 73 to 79, Fe in a weight percentage in a range from 17 to 23, Cu in a weight percentage in a range from 2 to 5, and Mo in a weight percentage in a range from 2 to 5.

10. The voice coil motor as described in claim 9, wherein the metallic film contains Ni in a weight percentage in a range from 76 to 78, Fe in a weight percentage in a range from 17 to 19, Cu in a weight percentage in a range from 3 to 4, and Mo in a weight percentage in a range from 2 to 4.

11. The voice coil motor as described in claim 8, wherein the substrate contains Ni in a weight percentage in a range from 78 to 82, and Fe in a weight percentage in a range from 18 to 22.

12. The voice coil motor as described in claim 8, wherein a thickness of the substrate is in a range from 50 μm to 1000 μm.

13. The voice coil motor as described in claim 12, wherein a thickness of the metallic film is in a range from 100 nm to 1000 nm.

14. The voice coil motor as described in claim 8, wherein the metallic film is formed on the entire outer surface of the substrate.

15. A voice coil motor, comprising an electromagnetic interference shielding shell, and a voice coil module received in the shell, the shell comprising a substrate made of an alloy of Ni and Fe; and a metallic film formed on at least one surface of the substrate, the metallic film being made of an alloy of Ni, Fe, Cu and Mo, and the metallic film being the inmost surface of the entire shell and directly facing the voice coil module.
